(19) United States
(12) Patent Application Publication
(10) Pub. No.: US 2013/0248914 A1
(43) Pub. Date: Sep. 26, 2013

(54) PACKAGED OPTOELECTRONIC DEVICE AND PROCESS FOR MANUFACTURING

(71) Applicants: Jeffrey Michael Youmans, Saratoga Springs, NY (US); Joseph John Shiang, Niskayuna, NY (US)

(72) Inventors: Jeffrey Michael Youmans, Saratoga Springs, NY (US); Joseph John Shiang, Niskayuna, NY (US)

(73) Assignee: GENERAL ELECTRIC COMPANY, SCHENECTADY, NY (US)

(21) Appl. No.: 13/424,536

(22) Filed: Mar. 20, 2012

(51) Int. Cl. H01L 33/62; H01L 31/18; H01L 31/0203; H01L 33/48

(52) U.S. Cl. 257/99; 257/433; 438/26; 438/64; 257/E33.056; 257/E33.066; 257/E31.124; 257/E31.117

(57) ABSTRACT

A packaged optoelectronic device and a method for manufacturing is provided. The packaged optoelectronic device includes at least one optoelectronic device with two electrodes sandwiched between a first barrier layer and a second barrier layer. At least one of the barrier layers comprises at least one aperture. Further, the packaged device includes a plurality of thin electrically conductive connectors. Each of the thin connectors extends out through the at least one aperture and is coupled to the anode or the cathode. Further, the thin connectors are connected to an external power source to provide power to the anode and the cathode.

### BACKGROUND

The present invention relates, generally, to the field of optoelectronic devices, and, specifically, to the field of packaged optoelectronic devices and methods for manufacturing.

Optoelectronic devices generally include a wide array of devices that include light emitting devices used in display systems or photovoltaic devices used in energy generation systems. Optoelectronic devices are structured to include an active layer disposed between two electrodes. In light emitting devices, when a power source connected between the two electrodes supplies electric energy to the two electrodes, current flows through the active layer and causes the active layer to emit light. On the other hand, in photovoltaic devices the active layer absorbs energy from light and converts this energy into electric energy. The electric energy can be fed to a load by connecting the load between the two electrodes of the photovoltaic device.

Manufacturing of optoelectronics devices includes approaches like vacuum deposition of semiconductor materials, usage of solution processed materials, and inkjet printing technology. In the vacuum deposition of semiconductor materials approach, a substrate made from non-conducting material like glass and plastic is used as a base and different layers of the optoelectronic device are deposited on the base. In inkjet printing technology, active layers are printed on a non-conducting substrate made from suitable materials.

Regardless of the construction of the device, it is necessary to pack the optoelectronic device in order to protect it from the deteriorating effects of moisture and oxygen exposure. While it is necessary to pack the optoelectronic device to keep moisture and oxygen away, it is also important to provide for mechanisms to connect the electrodes to a power source. Most Organic Light Emitting Diodes (OLEDs) provide for electrical connections through feed-through configuration. For an example, barrier films that are used for fabrication of OLEDs typically include a thin transparent oxide layer on a plastic film and provide electrical connections through electrical wires that sealed to the edges of the optoelectronic device with the help of conductive adhesives. However, with such a configuration, it has been observed that moisture and oxygen can permeate at the edges of the optoelectronic device. Further, intrinsic moisture in the adhesive can also permeate through the package and reach the active layers.

Thus, there is a need for an improved thin flexible packaging technology for low cost production of optoelectronic devices.

### BRIEF DESCRIPTION

Briefly, in one aspect, the present invention relates to a packaged optoelectronic device. The packaged optoelectronic device includes at least one optoelectronic device with a cathode and an anode. The at least one optoelectronic device is sandwiched between a first and a second barrier layer. Further the second barrier layer includes at least one aperture. Furthermore, the packaged optoelectronic device includes a plurality of thin electrically conductive connectors. Each of the thin electrically conductive connectors is coupled to at least one of the anode and the cathode. Furthermore, the thin electrically conductive connectors extend out of the packaged optoelectronic device from the at least one aperture to be configured to be connected to an external power source to provide power to at least one of the anode and the cathode.

In another aspect, the present invention relates to a packaged optoelectronic device that includes at least one optoelectronic device and at least one conductive bus line. The at least one optoelectronic device includes a cathode and an anode and is sandwiched between a first and a second barrier layer. The second barrier layer includes at least one aperture. Further, the conductive bus line is electrically coupled with at least one of the cathode and anode. The conductive bus line extends out of the packaged optoelectronic device through the at least one aperture.

In yet another aspect, the present invention relates to a process for manufacturing a packaged optoelectronic device. The process includes sandwiching an optoelectronic device between a first and a second barrier layer. The sandwiched optoelectronic device includes at least one anode and at least one cathode. Further, the process includes forming at least one aperture in the second barrier layer. The process further includes the step of passing at least one thin electrically conductive connector through the at least one aperture. Furthermore, the process includes the step of electrically coupling the at least one thin electrically conductive connector with at least one of the anode and the cathode.

In yet another aspect, the present invention relates to a packaged optoelectronic device including a first transparent barrier layer; a second barrier layer with at least one aperture; at least one optoelectronic device sandwiched between the first and second barrier layers, the optoelectronic device comprising an anode, and a cathode; a plurality of thin electrically conductive connectors coupled to the anode and the cathode; and a plurality of conductive bus lines electrically coupled to the plurality of thin electrically conductive connectors and extending out from the at least one aperture.

### DRAWINGS

These and other features, aspects, and advantages of the present invention will become better understood when the following detailed description is read with reference to the accompanying drawings in which like characters represent like parts throughout the drawings, wherein:

FIG. 1 is a cross-sectional view of an optoelectronic device sandwiched between two barrier layers;

FIG. 2 is a top view of a packaged optoelectronic device that includes a plurality of optoelectronic devices, according to certain embodiments of the invention;

FIG. 3 is a cross-sectional view of an optoelectronic device from the packaged optoelectronic device, according to an embodiment of the invention, taken along the line 3-3 of FIG. 2;

FIG. 4 is a top view of a packaged optoelectronic device including a conductive bus line, according to certain embodiments of the invention;

FIG. 5 is a cross-sectional view of an optoelectronic device, according to another embodiment of the present invention, taken along the line 5-5 of FIG. 4;

FIG. 6 is a schematic illustration of a process for manufacturing a packaged optoelectronic device.

### DETAILED DESCRIPTION

Reference will be made below in detail to exemplary embodiments of the invention, examples of which are illustrated in the accompanying drawings. Wherever possible, the same reference numerals used throughout the drawings refer to the same or like parts.

Embodiments of the invention described herein relate to a packaged optoelectronic device. The packaged optoelectronic device includes an optoelectronic device that is sandwiched between two barrier layers. Examples of the optoelectronic device include, but are not limited to, photovoltaic devices and light emitting devices. The optoelectronic devices include two electrodes, a cathode and an anode, which when connected to a power source allow the devices to either emit light or provide energy to the power source. When the electrodes of a light emitting optoelectronic device are connected to the power source and are excited by the power source, light is emitted. This phenomenon is used in display systems for mobile phones, television sets etc. Whereas, when the light is incident on photovoltaic devices, it provides electric energy through the electrodes to the connected power source. The present invention provides for mechanisms to electrically couple the electrodes of the optoelectronic device to the power source outside the package without letting moisture ingression. In the present invention, at least one aperture is provided in one of the two barrier layers. At least one thin electrically conductive connector is coupled to the electrodes and extended out of the at least one aperture. The electrically conductive connector is connected to a power source outside the package.

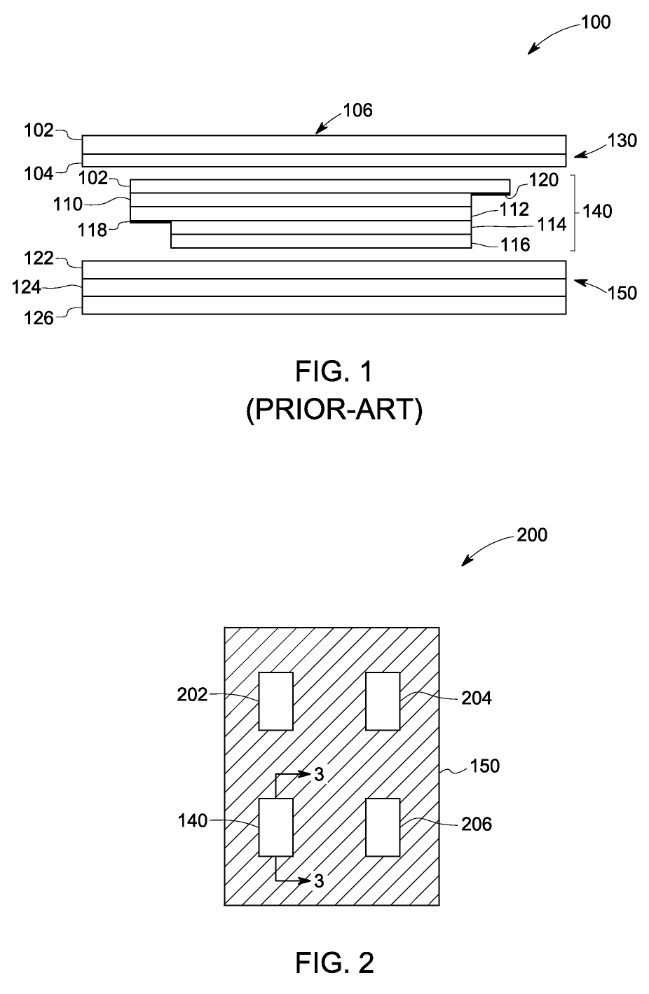

FIG. 1 illustrates a cross-sectional view of a single-pixel packaged optoelectronic device 100 as known in the art, which may be a light-emissive device, particularly, an OLED, or a light-absorbing device, such as a photovoltaic (PV) cell. The packaged optoelectronic device includes a first barrier layer 130, an optoelectronic device 140, and a second barrier layer 150. The first barrier layer 130 includes a plastic or glass substrate 102, and transparent barrier layer 104. The optoelectronic device 140 includes a transparent conductive layer 108 forming a first electrode (typically an anode), an optoelectronically active layer 110, and a second electrode 112 (cathode). In some embodiments, the transparent barrier layer 104 is present in a different location, and in others, the transparent barrier layer 104 is absent. Additional layers such as hole-injection, hole-transportation, electron injection and electron transportation layers are frequently included in an OLED, and may be present in a packaged optoelectronic device according to the present invention but are not critical. Layer 114 is an optional insulating layer that may be used to provide mechanical protection to the cathode 112 during fabrication and/or to prevent electrical shorting to other package elements during subsequent steps. Layer 116 is an optional barrier layer to protect the device. Each electrode, anode and cathode, has a contact to form electrical connections with an external power source. In the illustrated embodiments, anode has a contact 120 and cathode has a contact 118. In the device 100, surface 106 is the light emitting or light absorbing side.

The second barrier layer 150 includes a thin interface layer 122, a barrier layer 124, and optional insulating layer 126. Suitable materials for use as the second barrier layer 150 include commercially available multilayer packaging or lidding materials having moisture- and optionally oxygen-barrier properties in the form of films or sheets, especially heat-sealable materials. Lidding materials are typically composed of multiple thin polymer layers; lidding foils also include a metal foil, typically aluminum, sandwiched between polymer layers. One example of a suitable material for the second barrier layer 150 is Tolas TPC-0814B lidding foil, produced by Tolas Healthcare Packaging, Feasterville, Pa., a division of Oliver-Tolas, Grand Rapids, Mich.

The packaged optoelectronic device 100 is a single pixel device including only one optoelectronic device 140, but it is known in the art that individual pixels can be monolithically integrated in a series configuration (as illustrated in the top view of FIG. 2) to form a multi-pixel device configuration, and that the exact location of contacts 118 and 120 may be varied based on various design considerations. An array of optoelectronic devices 140 can also be formed in a configuration described in US20110186866, assigned to General Electric Company. It is known in the art that an optoelectronic device, particularly an OLED, can be fabricated in various configurations and by various processes. For example, U.S. Pat. Nos. 6,661,029, 6,700,322, 6,800,999 and 6,777,871, assigned to General Electric Company, describe OLED devices that may be included in a packaged optoelectronic device according to present invention, and methods for manufacturing them.

FIG. 2 illustrates a top view of a packaged optoelectronic device 200 that includes a plurality of optoelectronic devices 140 placed on the second barrier layer 150. In a multi-pixel configuration, multiple optoelectronic devices are placed on a single sheet of the second barrier layer 150. As shown in the illustrated embodiment, the second barrier layer 150 supports optoelectronic devices 140, 202, 204, and 206. Typically, size of an optoelectronic device 140 varies from 5 cm² to 100 cm². Based on the number of optoelectronic device 140 required for a particular operation, and the size of optoelectronic devices 140 being used, suitable size of the second barrier layer 150 is selected. The space between the optoelectronic devices 140, 202, 204, and 206 depends on the type of application for which the packaged optoelectronic device 200 is being used. The first barrier layer 130 is disposed on top of the series of optoelectronic devices 140, 202, 204, and 206. The edges of the first barrier layer 130 and the second barrier layer 150 are bonded to each other using an adhesive to avoid oxygen and moisture ingression.

It is also understood that a multi-pixel configuration of optoelectronic devices 140, 202, 204, and 206 can be formed by individually placing devices 140, 202, 204, and 206 between separate sheets of barrier layers 130 and 150. The individual packages thus formed are integrated to form a series configuration of single pixel optoelectronic devices. Further, multi-pixel optoelectronic device 200 can also be obtained by overlapping the optoelectronic devices 140, 202, 204, and 206 over each other to form a tile structure. The tile structure of the optoelectronic devices 140, 202, 204, and 206 is then sandwiched between the barrier layers 130 and 150 to form the packaged optoelectronic device 200.

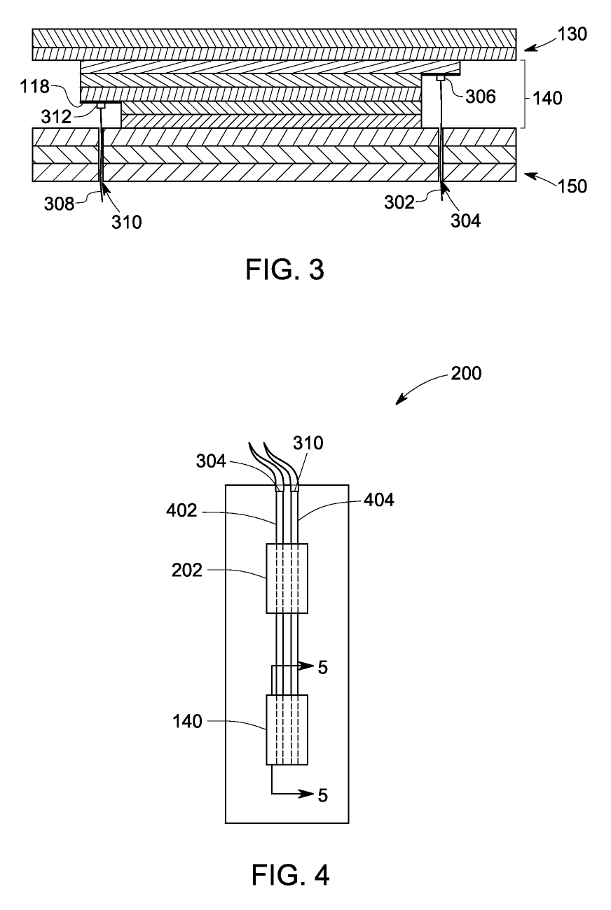

FIG. 3 is a cross-sectional view of the packaged optoelectronic device 200, according to an embodiment of the invention, taken along the line 3-3 of FIG. 2. The cross-sectional view includes the optoelectronic device 140, the second barrier layer 150 on which the optoelectronic device 140 is disposed, and the first barrier layer 130 which is disposed on top of the optoelectronic device 140 and bonded with the second barrier layer 150. As described in FIG. 1, the first barrier layer 130 includes substrate 102, and transparent barrier layer 104. The substrate 102 has a transparent surface 106 that emits light from the optoelectronic device 140. The optoelectronic device 140 includes transparent conductive layer 108 forming the first electrode (typically an anode), optoelectronically active layer 110, and the second electrode 112 (cathode). The second barrier layer 150 includes thin interface layer 122, barrier layer 124, and optional insulating layer 126. According to certain embodiments, at least one aperture 304 and 310 are formed in second barrier layer 150. The apertures 304 and 310 are formed using any suitable methods, including punching, die cutting, and laser machining. The apertures may be round, of varied diameter, or of other shapes and aspect ratios depending on the layout of the packaged device 200 and other design factors. Thin electrically conductive connectors 308 and 302 are electrically coupled to the cathode contact 118 and the anode contact 120 respectively. The thin electrically conductive connectors 302 and 308 are connected to the cathode contact 118 and the anode contact 120 with the help of blocks 312 and 306 made of adhesive material. The electrically conductive connectors 302 and 308 are extended out from the packaged optoelectronic device 200 through the apertures 304 and 310.

According to one embodiment of the present invention, the electrically conductive connectors 302 and 308 are composed of foils of a conductive metal, such as aluminum. The connectors 302 and 308 are selected based on the size of the apertures 304 and 310 made in the second barrier layer 150. The connectors 302 and 308 are selected such that no space is left in the apertures 304 and 310 for moisture, oxygen, and/or vapors to enter the packaged optoelectronic device 200. According to certain embodiments, aluminum foils of thickness less than or equal to 20 microns are used to make the thin electrically conductive connectors 302 and 308. Although only two apertures 304 and 310 are shown, in some embodiments, the second barrier layer 150 includes multiple, that is, more than two, apertures.

The blocks 306 and 312 are formed from electrically conductive adhesive material placed by various means, including manual or automated means. An example of a suitable material for the blocks 306 and 312 is Staystik 571, available from Cookson Electronics, Alpharetta, Ga. The second barrier layer 150 and optoelectronic device 140, electrically conductive connectors 302 and 308, and contacts 118 and 120 are then aligned and layed up in preparation for lamination process at a temperature between 90° C. and 130° C., preferably at 120° C., and a pressure of 1 psi to 30 psi, and preferably 15 psi, for a time between 1 second and 10 minutes, and preferably 30 seconds. In the resulting package, the electrically conductive connectors 302 and 308 make electrical connections with contacts 118 and 120 through the blocks 306 and 312. The apertures 304 and 310, connectors 302 and 308 and blocks 306 and 312 can be, optionally, centered and aligned.

Various lamination means are possible, including pouch lamination, roll lamination and hot press lamination, and process parameters depend on the equipment utilized. It is apparent that release films, press pads, and tooling plates are necessary to perform these laminations. Moreover, steps to clean and remove moisture from all package materials may be performed during processing. For example, the second barrier layer 150 may be baked at 80° C. for 12 hours under vacuum to eliminate moisture; however, other conditions may be used, including shorter times at higher temperatures under an inert atmosphere. The conditions will depend on the prior environmental exposure of the materials.

FIG. 4 shows a top view of a packaged optoelectronic device 200 according to another embodiment. The packaged optoelectronic device 200 includes second barrier layer 150, disposed on which are optoelectronic devices 140, and 202. The packaged optoelectronic device 200 can include more than 2 optoelectronic devices 140. The packaged optoelectronic device 200 also includes first barrier layer 130 that is disposed on top of the optoelectronic devices 140, 202, 204, and 206 and bonded to the second barrier layer 150. The packaged optoelectronic device 200 includes conductive bus lines 402 and 404. The conductive bus lines 402 and 404 flow along the length or breadth of the second barrier layer 150. According to certain embodiments the conductive bus line 402 is a cathode bus line and the conductive bus line 404 is an anode bus line. The cathode bus line 402 electrically couples the cathode contacts 118 of all the optoelectronic devices 140 to a negative terminal of the external power source, whereas as the anode bus line 404 electrically couples the anode contacts 120 of all the optoelectronic devices 140 to a positive terminal of the external power source.

The conductive bus lines 402 and 404 are made from conductive material like aluminum, steel, nickel, or brass. At least one of the thin electrically conductive connectors 302 and 308 is electrically coupled to one of the conductive bus line 402 and 404 by means of conductive adhesive material. The conductive bus lines 402 and 404 are extended out from the at least one of the apertures 304 and 310. According to certain embodiments, the conductive bus lines are disposed between the first barrier layer 130 and the optoelectronic device 140. According to other embodiments, the conductive bus lines are disposed between the optoelectronic device 140 and the second barrier layer 150. The connectors 302 and 308 are attached perpendicular to the bus lines. According to certain embodiments, the connectors 302 and 308 are attached parallel to the bus lines 402 and 404.

In the multi-pixel configuration of optoelectronic devices 140, where individual optoelectronic devices 140 are packaged separately and then integrated in a series configuration, the conductive bus lines 402 and 404 are extended out of one packaged optoelectronic device 200 from the apertures and extended to another packaged optoelectronic device 200 where they are electrically coupled to cathode and anode contacts of the other packaged optoelectronic device 200, respectively.

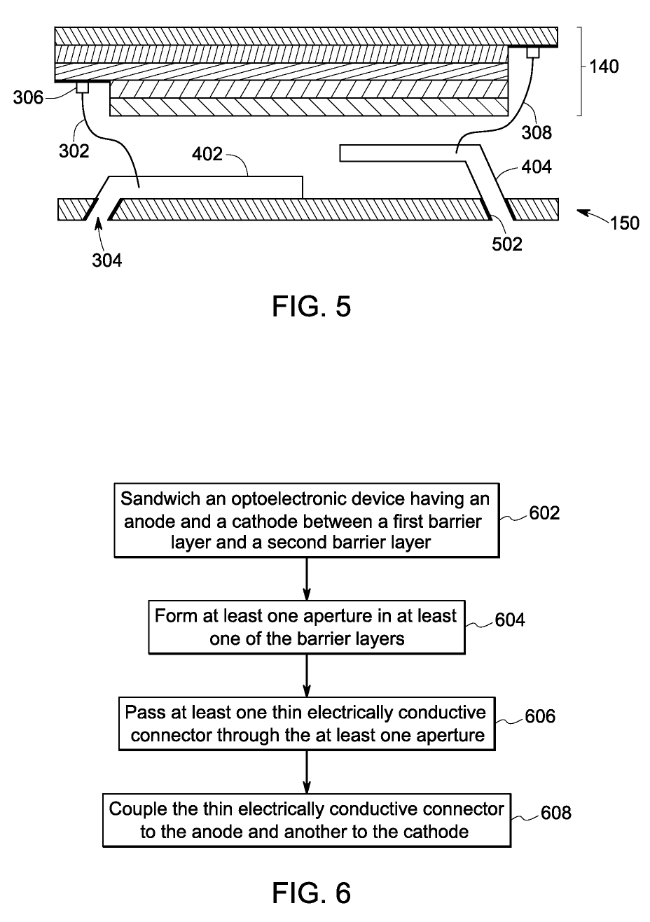

FIG. 5 shows a cross-sectional view of the packaged optoelectronic device 200, according to certain embodiments, taken along the line 5-5 of FIG. 4. The packaged optoelectronic device 200, as discussed earlier, includes optoelectronic device 140, second barrier layer 150 and first barrier layer 130 (not shown). Electrically conductive connectors 302 and 308 are connected to the contacts 118 and 120 through blocks 306 and 312. The blocks 306 and 312 are made from conductive adhesive material. The conductive connectors 302 and 308 are electrically coupled with the conductive bus lines 402 and 404. The conductive bus lines 402 and 404 are extended out of the apertures 304 and 310 and are connected to external power source.

In the packaged optoelectronic device 200, according to one embodiment, all electrically conductive connectors 308 connected to the cathode contact 118 of the optoelectronic devices 140, 202, 204, and 206 are connected to the conductive bus lines 402. Further, all the electrically conductive connectors 302 connected to the anode contact 120 of the optoelectronic devices 140, 202, 204, and 206 are connected the conductive bus lines 404. Further, in certain embodiments, the conductive bus line 402 is electrically coupled with the cathode contacts 118 of the optoelectronic devices 140, 202, 204, and 206 through direct contact, i.e. not through electrically conductive connectors 308. In certain embodiments, the cathode contacts 118 are electrically coupled to the power source through the conductive bus line 402, whereas the anode contacts 120 are electrically coupled to the power source through the electrically conductive connectors 302. Contact between the conductive bus lines 402 is avoided by disposing the conductive bus lines 402 in parallel fashion along the width of the packaged optoelectronic device 200

According to certain embodiments, insulation layer 502 is deposited along a periphery of the apertures 304 and 310. The insulation layer 502 protects thin electrically conductive connectors 302 and 308, and/or the conductive bus lines 402 from coming in contact with other components of the packaged optoelectronic device 200 and cause electric shorting.

FIG. 6 is a schematic illustration of a process for manufacturing a packaged optoelectronic device. At step 602, at least one optoelectronic device 140 is sandwiched between the first barrier layer 130 and the second barrier layer 150. The optoelectronic devices 140 are provided on a sheet composed of multiple individual devices disposed on a substrate, without a transparent barrier layer. The number and configuration of the optoelectronic devices on the sheet is not critical, and, in some embodiments, the sheet may be composed of a single large element. The sheet containing optoelectronic devices 140 may be prefabricated and provided in roll format, or may be fabricated on the same roll-to-roll line. The second barrier layer 150 is composed of a multilayer film as described previously, and provided in roll format. The first barrier layer 130 is formed by disposing on the substrate 102 the transparent barrier layer 104. Alternately, the first barrier layer 130 may be pre-coated and provided in roll format. In some embodiments, when the sheet containing optoelectronic devices 140 includes a transparent barrier layer; the transparent barrier layer 104 is not provided on the first barrier layer 130. In other embodiments, the first barrier layer 130 is omitted if the sheet carrying optoelectronic devices has the transparent barrier layer 104. In such situations the sheet carrying optoelectronic devices 140 are the second barrier layer 150 are laminated together. At step 604, plurality of apertures 304 and 310 are formed on the second barrier layer 150. At step 606, at least one thin electrically conductive connector 302 and 308 are passed through the apertures 304 and 310. The thin electrically conductive connectors 302 and 308 are chosen to occupy all the space in the apertures 304 and 310. Further, at step 608, the thin electrically conductive connectors 302 and 308 are electrically coupled with the electrodes of the optoelectronic device 140. Conductive adhesive material is applied to the cathode contact 118 and the anode 120 to provide a means for electrically coupling the connector 308 to the anode and the connector 302 to the cathode of the device 140. The first barrier layer 130, the sheet carrying optoelectronic devices 140, and the second barrier layer 150 are laminated together in such a way that the device 140 is sandwiched between the first barrier layer 130 and the second barrier layer 150. In embodiments where the first barrier layer 130 is omitted, only sheet carrying optoelectronic devices 140 and the second barrier layer 150 are laminated. In alternate embodiment, the apertures 304 and 310 are formed after the first barrier layer 130, the optoelectronic device 140, and the second barrier layer 150 are laminated together, and the connectors 302 and 308 are inserted thereafter.

Various embodiments of the packaged optoelectronic device and method for manufacturing provide for flexible packaged optoelectronic devices with low cost of production. Further, the packaged optoelectronic device described in the application provides for a solution to the problem of moisture and oxygen ingression observed in optoelectronic packaging.

It is to be understood that the above description is intended to be illustrative, and not restrictive. For example, the above-described embodiments (and/or aspects thereof) may be used in combination with each other. In addition, many modifications may be made to adapt a particular situation or material to the teachings of the invention without departing from its scope. While the dimensions and types of materials described herein are intended to define the parameters of the invention, they are by no means limiting and are exemplary embodiments. Many other embodiments will be apparent to those of ordinary skill in the art upon reviewing the above description. The scope of the invention should, therefore, be determined with reference to the appended claims, along with the full scope of equivalents to which such claims are entitled. In the appended description, the terms “including” and “in which” are used as the plain-English equivalents of the respective terms “comprising” and “wherein.” Moreover, in the following claims, the terms “first,” “second,” etc. if any, are used merely as labels, and are not intended to impose numerical or positional requirements on their objects. Further, the limitations of the following claims are not written in means-plus-function format and are not intended to be interpreted based on 35 U.S.C. §112, sixth paragraph, unless and until such claim limitations expressly use the phrase “means for” followed by a statement of function void of further structure.

This written description uses examples to disclose several embodiments of the invention, including the best mode, and also to enable any person of ordinary skill in the art to practice the embodiments of invention, including making and using any devices or systems and performing any incorporated methods. The patentable scope of the invention is defined by the claims, and may include other examples that occur to those of ordinary skill in the art. Such other examples are intended to be within the scope of the claims if they have structural elements that do not differ from the literal language of the claims, or if they include equivalent structural elements with insubstantial differences from the literal languages of the claims.

As used herein, an element or step recited in the singular and proceeded with the word “a” or “an” should be understood as not excluding plural of said elements or steps, unless such exclusion is explicitly stated. Furthermore, references to “one embodiment” of the present invention are not intended to be interpreted as excluding the existence of additional embodiments that also incorporate the recited features. Moreover, unless explicitly stated to the contrary, embodiments “comprising,” “including,” or “having” an element or a plurality of elements having a particular property may include additional such elements not having that property.

While only certain features of the invention have been illustrated and described herein, many modifications and changes will occur to those skilled in the art. It is, therefore, to be understood that the appended claims are intended to cover all such modifications and changes as fall within the true spirit of the invention.

What is claimed is:

1. A packaged optoelectronic device comprising
at least one optoelectronic device with a cathode and an anode sandwiched between a first and a second barrier layer, wherein at least one of the barrier layers comprises at least one aperture;
a plurality of thin electrically conductive connectors, each extending out of the packaged optoelectronic device through the at least one aperture, and coupled at least one of the anode and the cathode, and configured to be connected to an external power source to provide power to at least one of the anode and the cathode.

2. The packaged optoelectronic device according to claim 1, wherein the second barrier layer comprises a multilayer structure.

3. The packaged optoelectronic device according to claim 2, wherein the multilayer structure comprises at least one metal layer.

4. The packaged optoelectronic device according to claim 3, wherein the at least one metal layer comprises aluminum, stainless steel or brass.

5. The packaged optoelectronic device according to claim 1, wherein the plurality of thin electrically conductive connectors comprises conductive foils.

6. The packaged optoelectronic device according to claim 1, wherein the at least one aperture comprises a slit.

7. The packaged optoelectronic device according to claim 1 further comprises conductive adhesive material to electrically couple the plurality of thin electrically conductive connectors with the anode and the cathode.

8. The packaged optoelectronic device according to claim 1 further comprises at least one conductive bus line, wherein the plurality of thin electrically conductive connectors are electrically coupled with the at least one conductive bus line.

9. The packaged optoelectronic device according to claim 1 further comprises electrical insulation along a periphery of the at least one aperture.

10. The packaged optoelectronic device according to claim 1, wherein at least one of the plurality of thin electrically conductive connectors are connected to the anode and at least one of the remaining thin electrically conductive connectors is connected to the cathode.

11. The packaged optoelectronic device according to claim 1 further comprises a cathode conductive bus line and an anode conductive bus line, wherein the thin electrically conductive connectors coupled with the anode are coupled with the anode conductive bus line, and the thin electrically conductive connectors coupled with the cathode are coupled with the cathode conductive bus line.

12. A packaged optoelectronic device comprising
at least one optoelectronic device having a cathode and an anode sandwiched between a first and a second barrier layer, wherein at least one of the barrier layers comprises at least one aperture; and
at least one conductive bus line electrically coupled with at least one of the cathode and the anode, wherein the at least one conductive bus line extends out of the packaged optoelectronic device through the at least one aperture.

13. The packaged optoelectronic device according to claim 12 further comprises a conductive adhesive layer to couple the at least one of the cathode and anode with the at least one conductive bus line.

14. A process for manufacturing a packaged optoelectronic device, said process comprising
sandwiching an optoelectronic device having an anode and a cathode between a first barrier layer and a second barrier layer;
forming at least one aperture in at least one of the barrier layers;
passing at least one thin electrically conductive connector through the at least one aperture; and
coupling at least one of the thin electrically conductive connectors to at least one of the anode and the cathode . . . .

15. The process according to claim 14 further comprises disposing insulation material along a periphery of the at least one aperture.

16. The process according to claim 14 further comprises disposing at least one conductive bus line between the first barrier layer and the second barrier layer.

17. The process according to claim 16 further comprises disposing the at least one conductive bus line between the first barrier layer and the at least one optoelectronic device.

18. The process according to claim 16 further comprises disposing the at least one conductive bus line between the second barrier layer and the at least one optoelectronic device.

19. The process according to claim 14 further comprises coupling at least one of the thin electrically conductive connector with the cathode and at least one separate thin electrically conductive connector with the anode.

20. A packaged optoelectronic device comprising:
a first transparent barrier layer;
a second barrier layer, wherein the second barrier layer comprises at least one aperture;
at least one optoelectronic device sandwiched between the first transparent barrier layer and the second barrier layer, wherein the optoelectronic device comprises a cathode, and an anode;
a plurality of thin electrically conductive connectors, wherein at least one connector is connected to the anode and at least one other connector is connected to the cathode; and
a plurality of conductive bus lines extending out through the at least one aperture, wherein at least one conductive bus line is coupled with the at least one connector connected to the anode and at least one other conductive bus line is coupled the at least one connector connected to the cathode.
